(19) United States
(12) Patent Application Publication
(10) Pub. No.: US 2003/0096517 A1
(43) Pub. Date: May 22, 2003

(54) Electrical connector

(76) Inventor: Yi-Tse Ho, Tainan Hsien (TW)

Correspondence Address: MOLEX INCORPORATED, 2222 WELLINGTON COURT, LISLE, IL, 60532, US

(21) Appl. No.: 10/301,291

(22) Filed: Nov. 21, 2002

(30) Foreign Application Priority Data
Nov. 21, 2001 (TW) 90220125

(51) Int. Cl. H05K 1/00; H01R 12/00

(52) U.S. Cl. 439/79

(57) ABSTRACT

The present invention provides an electrical connector which includes an insulating housing and a plurality of terminals for electrical connection with a circuit board and for coupling with a matching electrical connector. The insulating housing has a connecting face, an end face disposed opposite and parallel to the connecting face, and a mating face that is adjoined to the end face at a right angle. The connecting face is further provided with a power socket region and a signal socket region. The end face is provided with a plurality of terminal passages communicated with the power socket region and the signal socket region. The end face is further provided with a projecting flange. The flange is provided with a plurality of recesses corresponding in position to the terminal passages. The conductive terminal has a connecting end disposed in the corresponding terminal passage, a mating end in electrical contact with the circuit board, and a securing portion connecting the connecting and the mating end and received in the recess. By arranging the connecting face and the mating face of the insulating housing at a right angle to each other, the matching electrical connector can be coupled to the connecting face in a direction parallel to the extending direction of the circuit board.

### FIELD OF THE INVENTION

This invention relates to an electrical connector, more particularly to the use of an electrical connector connected electrically to a circuit board to simultaneously transmit electric power and electronic signals such that the direction of extension of a connecting face of the electrical connector is perpendicular to that of the circuit board to permit a matching electrical connector to mate with the electrical connector in a form parallel to the extension direction of the circuit board during mating, thereby effectively reducing the space occupied by the product in vertical height.

### BACKGROUND OF THE INVENTION

Reference is made to FIG. 1, which illustrates an electrical connector 4 connected electrically to a circuit board 5. The electrical connector 4 complies with a high-speed sequence transmission specification so as to have the capability of transmitting electric power and electronic signals simultaneously, which is the so-called electrical connector of the Serial ATA standard. Since the electrical connector 4 can simultaneously supply electric currents of different voltage values and high-speed transmission electronic signal data, it is quite suitable for electrical connection between a small-sized hard disk 6 and the circuit board 5. As shown, in terms of the arrangement of electrical connector 4 specified under the current Serial ATA standard, the electrical connector 4 includes an insulating housing 41 and a plurality of conductive terminals 42 disposed in the insulating housing 41. The insulating housing 41 has a connecting face 4101 disposed at an upper end, and a mating face 4102 parallel to the connecting face 4101 and disposed on the bottom portion of the opposite side so as to be proximate to the circuit board 5. The connecting face 4101 is disposed to connect with a matching electrical connector 61 on the small-sized hard disk 6. The connecting face 4101 is provided with a power socket 411 and a signal socket 412 that are depressed in the direction of the mating face, and a signal socket 412. Each conductive terminal 42 has a connecting end 421 and a mating end 422 opposite to the connecting end 421 such that when each conductive terminal 42 is received in the insulating housing 41, the mating end 422 can project from the mating face 4102 to be soldered to the circuit board 5. The connecting end 421 of each conductive terminal 42 can be disposed in the power socket 411 or the signal socket 412 for electrical contact with the corresponding terminal of the matching electrical connector 61 so as to transmit power or electronic signals.

However, it can be seen from the drawings that the current electrical connector 4 of the Serial ATA standard which is capable of transmitting power and electronic signals simultaneously is generally disposed perpendicular to the circuit board 5, which means that when an electronic device, such as the small-sized hard disk 6, is to be connected electrically to the circuit board 5, it has to be coupled with the electrical connector 4 in a manner that it is perpendicular to the direction of extension of the circuit board 5. For a housing (not shown) of a desk-top computer device or server, etc., which has a certain interior space, such a manner of connection is still feasible since the small-sized hard disk 6 has a small size. However, for a portable electronic device, such as a notebook computer, a personal digital assistant (PDA), which emphasizes lightness and compactness, since the vertical height of the product space cannot possibly be larger than the length of the small-sized hard disk 6, such a manner of vertical connection is not feasible. Therefore, there is a need to develop an electrical connector that enables an electronic device, such as the small-sized hard disk 6, to connect with the circuit board 5 in a direction parallel to the direction of extension of the circuit board 5 while complying with the Serial ATA standard for electrical connectors.

### SUMMARY OF THE INVENTION

Therefore, the main object of the present invention is to provide an electrical connector that enables a matching electrical connector to be coupled thereto in a direction parallel to the direction of extension of the circuit board so as to effectively reduce product height.

Accordingly, the electrical connector of the present invention includes an insulating housing and a plurality of conductive terminals for electrical connection with a circuit board and for coupling with a matching electrical connector.

The insulating housing has a connecting face disposed to couple with the matching electrical connector, an end face disposed opposite to the connecting face and parallel to the connecting face, and a mating face connected to the end face at a right angle and contacting the circuit board, the connecting face further having disposed thereon a power socket region and a signal socket region that are recessed in the direction of the end face, the end face being provided with a plurality of terminal passages that are communicated with the power socket region and the signal socket region, the end face being further provided with a flange that projects in a direction away from the end face, the flange being provided with a plurality of recesses that correspond in position to the terminal passages. The plurality of recesses make include recesses of different sizes so as to locate the contact portions of the terminals in different positions relative to the connecting face of the housing.

The terminal has a connecting end disposed in the corresponding terminal passage, a mating end disposed to electrically contact the circuit board, and a securing portion connecting the connecting end and the mating end, the connecting end having a front end which is provided with a contact portion to electrically contact the matching electrical connector, the securing portion being received in the corresponding limiting groove to be positioned relative to the insulating housing. By arranging the connecting face and the mating face of the insulating housing at a right angle to each other, the matching electrical connector can be coupled to the connecting face in a direction parallel to the direction of extension of the circuit board, and can establish electrical contact with the contact portions of the corresponding conductive terminals in the power socket region and the signal socket region.

### BRIEF DESCRIPTION OF THE DRAWINGS

The organization and manner of the structure and operation of the invention, together with further objects and advantages thereof, may best be understood by reference to the following description, taken in connection with the accompanying drawings, wherein like reference numerals identify like elements in which:

FIG. 1 is a perspective view of an electrical connector, illustrating the relationship between the electrical connector and a circuit board and a small-sized hard disk in assembly;

FIG. 2 is an exploded view showing the structure of the preferred embodiment of an electrical connector according to the present invention;

FIG. 3 is a perspective view of the preferred embodiment of FIG. 2 after assembly, illustrating the relationship between the electrical connector and a circuit board in assembly;

FIG. 4 is a perspective view of the preferred embodiment of FIG. 3 taken from another angle, showing a mating face of the electrical connector;

FIG. 5 is a perspective view of the preferred embodiment of FIG. 3 taken from another angle, illustrating the relationship between the connecting face and a small-sized hard disk in assembly;

FIG. 6 is a sectional view of FIG. 3 taken along line I-I; and

FIG. 7 is a sectional view of FIG. 3 taken along line II-II.

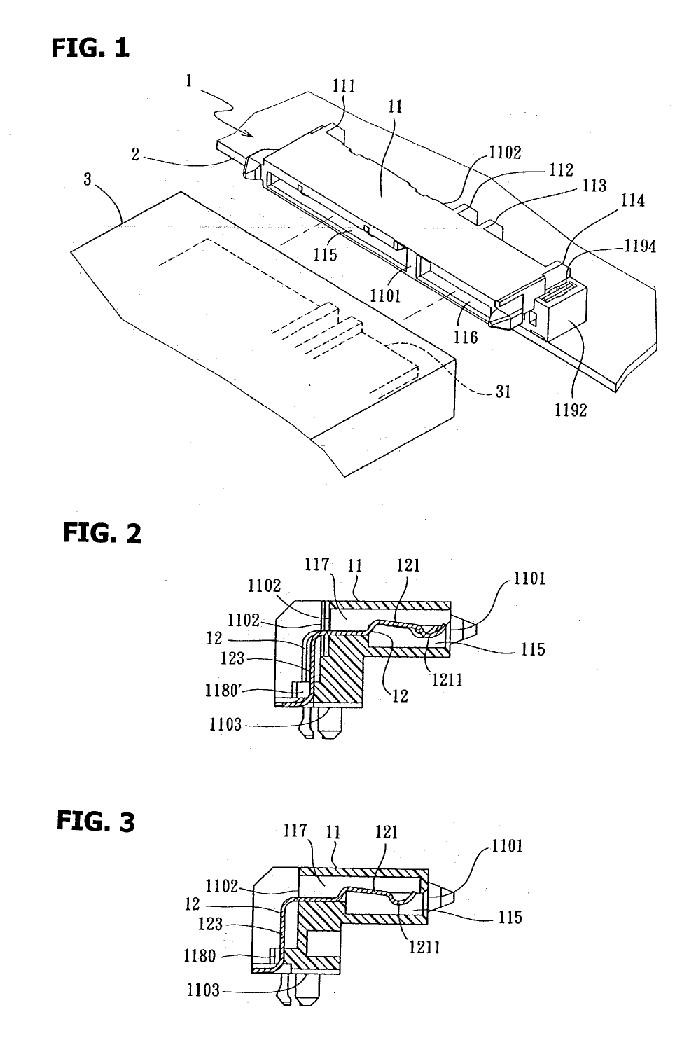

### DETAILED DESCRIPTION OF THE PREFERRED EMBODIMENT

While the invention may be susceptible to embodiment in different forms, there is shown in the drawings, and herein will be described in detail, a specific embodiment with the understanding that the present disclosure is to be considered an exemplification of the principles of the invention, and is not intended to limit the invention to that as illustrated and described herein.

Referring to FIGS. 2 to 5, the preferred embodiment of an electrical connector 1 according to this invention includes an insulating housing 11 and a plurality of terminals 12. The electrical connector 1 can be connected electrically to a circuit board 2 and can be coupled with a matching electrical connector 31 disposed on a small-sized hard disk 3.

The insulating housing 11 is substantially flat and elongated, and has a long direction and a short direction perpendicular to the long direction, a connecting face 1101 disposed at a front end of the insulating housing 11 along the long direction, a rear end of the insulating housing 11 forming an end face 1102 that is opposite to the connecting face 1101 and that is substantially parallel to the connecting face 1101, a bottom portion of the insulating housing forming a mating face 1103 that is interposed between the end face 1102 and the connecting face 1101 and that is perpendicularly connected to the end face 1102 and the connecting face 1101. In addition, two lateral sides of the short direction of the insulating housing 11 are adjoined to the connecting face 1101, the end face 1102 and the mating face 1103 to become a first lateral side 1104 and a second lateral side 1105, respectively. As shown in FIG. 5, the insulating housing 11 has a power socket region 115 and a signal socket 116 disposed on the connecting face 1101 thereof to extend in the direction of the end face 1102. As shown in FIG. 2, a first partition wall 111, a second partition wall 112, a third partition wall 113 and a fourth partition wall 114 are provided on the end face 1102 in a direction away from the end face 1102. A plurality of power terminal passages 117 are provided between the first partition wall 111 and the second partition 112 in positions corresponding to the power socket region 115 so as to be communicated with the end face 1102 and the power socket region 115. Signal terminal passages 117′ are likewise provided between the third partition wall 113 and the fourth partition wall 114 in positions corresponding to the signal socket region 116 so as to be communicated with the end face 1102 and the signal socket region 116. Further, the power terminal passages 117 and the signal terminal passages 117′ at the end face 1102 are relatively formed with a plurality of terminal holes, and the end face 1102 projects outwardly to a certain distance to form a protruding flange 118. The flange 118 is provided with a plurality of recesses 1180 that correspond respectively in position to the terminal holes formed in the end face 1102 by the power terminal passages 117 and the signal terminal passages 117′.

The power terminals in the power terminal passages 117 are disposed to be used for power transmission. The signal terminals in the signal terminal passages 117′ are disposed to be used for electronic signal transmission. The power terminals and the signal terminals in this preferred embodiment employ terminals of identical form and construction. Therefore, in the following description, the two types of terminals are denoted by terminals 12 in general. Each terminal 12 has a horizontally extending connecting end 121, a mating end 122 having a height difference with respect to the connecting end, and a securing portion 123 connecting the connecting end 121 and the mating end 122 and being substantially upright. The connecting end 121 of each terminal 12 extends through the corresponding power terminal passage 117 or signal terminal passage 117′ and is positioned in the power socket region 115 or signal socket region 116 adjacent to the connecting face 1101. The securing portion 123 is received in corresponding recess 1180. The mating portion 122 is substantially located at a position coplanar with the mating face 1103, and is prevented from deviating to the two sides due to retention of the securing portion 123 in the recess 1180.

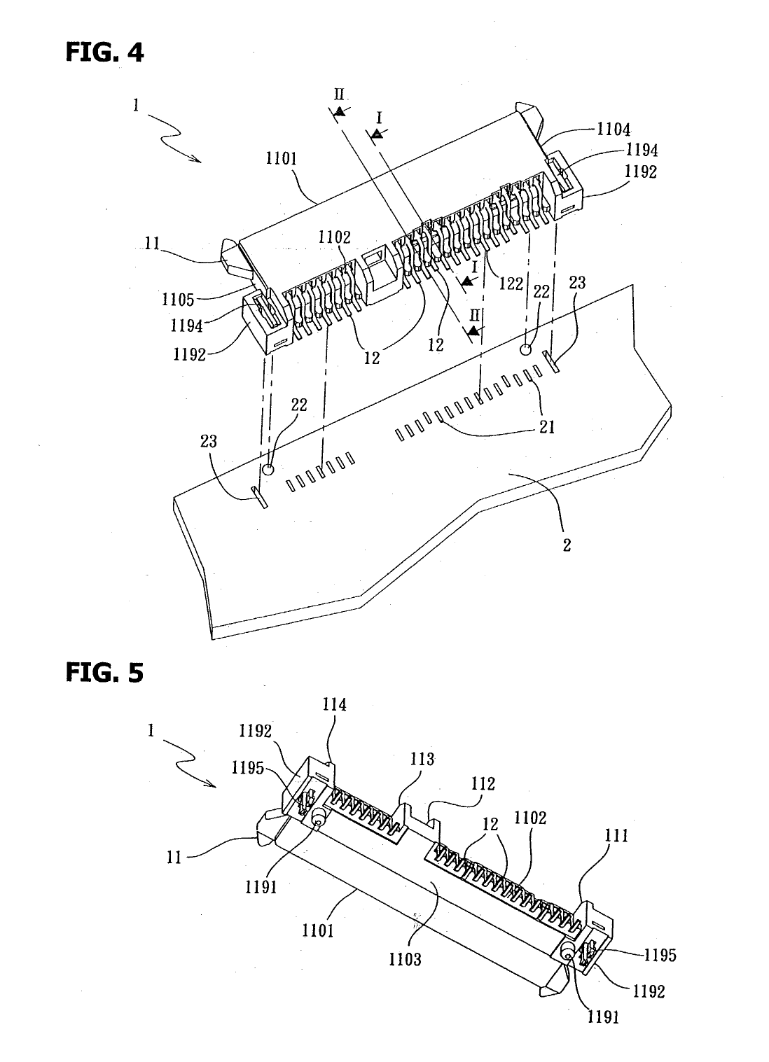

As shown in FIG. 3, FIG. 4 and FIG. 5, the mating face 1103 of the electrical connector 1 is disposed to contact the circuit board 2 such that the mating end 122 of each terminal 12 can be soldered to a corresponding contact 21 on the circuit board 2, and the electrical connector 1 utilizes the connecting ends 121 of the terminals 12 disposed in the power socket region 115 or signal socket region 116 to establish electrical contact with the corresponding terminals in the matching electrical connector 31 of the small-sized hard disk 3. The terminals 12 in the power socket region 115 are disposed to supply power to the small-sized hard disk 3, and the terminals 12 in the power signal region 116 are disposed to transmit electronic signals between the small-sized hard disk 3 and the circuit board 2. Since the electrical connector 1 is configured to have a low profile that the connecting face 1101 forms an inside angle of 90 degrees with the mating face 1103, it is capable of effectively cooperating with a notebook computer or a personal digital assistant or the like that demands an interior space design of a smaller vertical height.

Referring to FIG. 3 and FIG. 4, in order to enhance positioning of the electrical connector 1 relative to the circuit board 2, a positioning device 119 can be additionally provided on the insulating housing 11. In this embodiment, the positioning device 119 includes positioning posts 1191 on the mating face 1103 of the insulating housing 11 and projecting in a direction away from the mating face 1103, and the circuit board 2 is provided with positioning holes 22 corresponding in position to the positioning posts 1191, respectively. When the insulating housing 11 contacts the surface of the circuit board 2 with the mating face 1103, the positioning posts 1191 can fit into the positioning holes 22 so as to position the insulating housing 11 on the circuit board 2. In addition, the first lateral side 1104 and the second lateral side 1105 of the insulating housing 11 are further provided with outwardly protruding lug portions 1192. Each lug portion 1192 has a receiving hole 1193 disposed perpendicular to the mating face 1103 and extending through the lug portion 1192. Furthermore, each of the receiving holes 1193 receives a plate locking element 1194. The plate locking element 1194 has an elastic engaging portion 1195 which is capable of elastic deformation and which has a free end in the form of two outwardly protruding hooks. The elastic engaging portion 1195 can project from the lug portion 1192 when the plate locking element 1194 extends through and is positioned in the respective receiving hole 1193. The circuit board 2 is provided with fastening holes 23 corresponding in position to the plate locking elements 1194, respectively. During assembly of the insulating housing 11 and the circuit board 2, by means of the elastic engaging portions 1195 that are retained and secured in the fastening holes 23, the positioning of the insulating housing 11 and the circuit board 2 can be further enhanced.

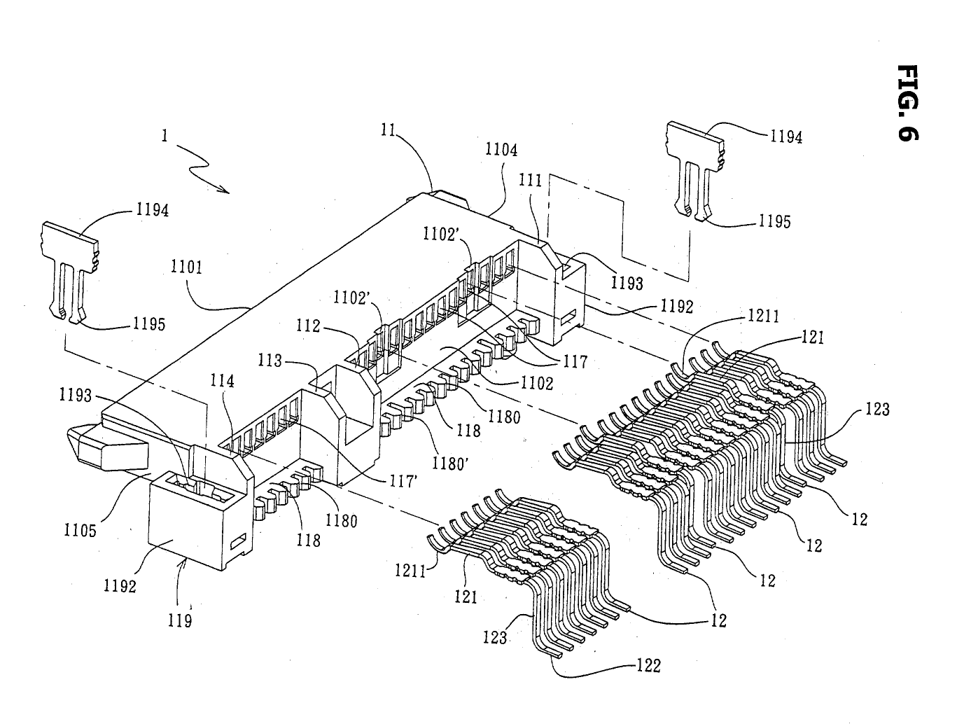

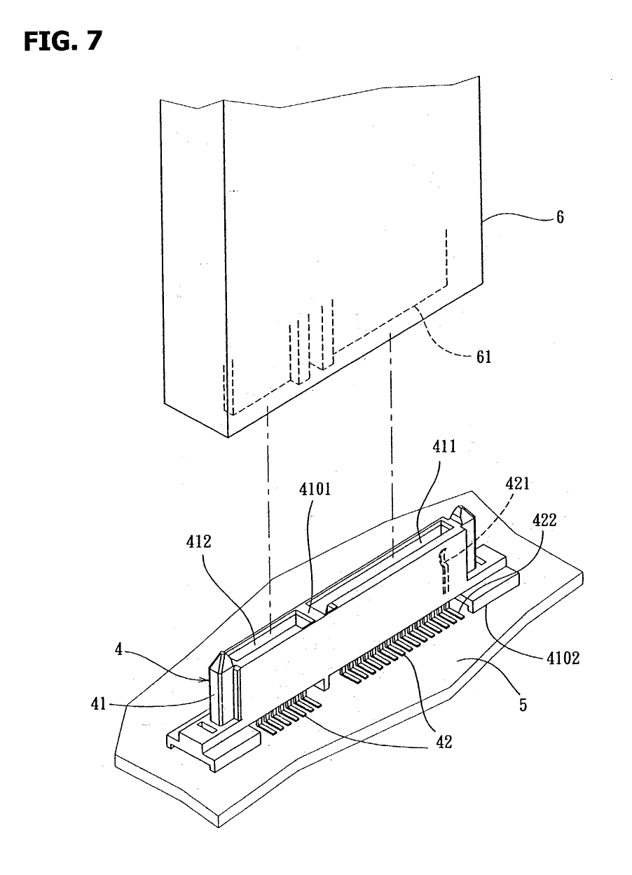

With further reference to FIGS. 2, 3, 6 and 7, in actual fabrication of the electrical connector 1, for purposes of meeting specification requirements, terminals 12 at certain specific positions have to project further forwardly to be disposed close to the connecting face 1101. For instance, as shown in FIG. 2, of the group of terminals 12 to be correspondingly extended into the power socket region 115, the contact portion 1211 of the fourth terminal to the left of the rightmost terminal and that of the fourth terminal to the right of the leftmost terminal have to be disposed closer to the connecting face 1101 than the contact portions 1211 of the rest of the conductive terminals 12. Under the condition that such a requirement can be met without the need for another type of terminal 12, the recesses 1180 in the flange 118 of the insulating housing 11 are further divided into recesses 1180 of a first category and recesses 1180′ of a second category such that the depth of the recesses 1180 of the first category that are depressed toward the connecting face 1101 remains unchanged (as shown in FIG. 7), whereas the depth of the recesses 1180′ of the second category is greater than that of the recesses 1180 of the first category (as shown in FIG. 6) so that the recesses 1180′ of the second category can correspond to the terminals 12 at such specific positions and such that the contact portions 1211 of the connecting ends 121 of the terminals 12 disposed in the recesses 1180′ of the second category can further project a certain distance toward the connecting face 1101. In addition, as shown in FIGS. 2 and 3, a recessed face 1102′ that is depressed toward the connecting face 1101 is provided in the end face 1102 of the insulating housing 11 in a position corresponding to the recesses 1180′ of the second category such that the terminal passage 117 which corresponds to and which is communicated with the recessed face 1102′ has a length shorter than that of its adjacent terminal passages 117 so that the securing portions 123 of the terminals 12 that are relatively more forward toward the connecting face 1101 in position are able to maintain with the recessed face 1102′ the same clearance as that present between the securing portions 123 of the other terminals 12 and the end face 1102.

Summing up the foregoing, the present invention is mainly directed to the arrangement of the connecting face 1101 and the mating face 1103 at a right angle to each other while complying with the Serial ATA standard for electrical connectors. Moreover, in conjunction with such a design, the insulating housing 11 is further configured to have the recesses 1180 that enhance the positioning of the conductive terminals 12, whereby the electronic device which utilizes the electrical connector 1 to connect electrically with the circuit board 2 can be mounted in parallel to the direction of extension of the circuit board 2 to thereby reduce the height of the entire product considerably, and has a higher applicability for portable electronic products that demand lightness and compactness.

However, the foregoing is merely a description of the preferred embodiment of the present invention and should not be based upon to limit the scope of practice of this invention. That is, any simple equivalent changes and modifications that are made in accordance with the claims of the present invention and the contents of the specification of the present invention should be deemed to fall within the scope of the claims of the present invention.

1. An electrical connector for electrical connection with a circuit board and for coupling with a matching electrical connector, said electrical connector comprising:
an insulating housing having a front end and a rear end, said front end having a connecting face for coupling with the matching electrical connector, said rear end having an end face parallel to said connecting face, a mating face disposed between said connecting face and said end face and adjoining said end face at a right angle so as to contact the circuit board, said connecting face being further partitioned into a power socket region and a signal socket region which extend in the direction of said end face, said power socket region and said signal socket region being respectively connected to a plurality of terminal passages that are communicated with said end face, said end face being provided with a flange projecting from said end face, said flange being provided with a plurality of recesses that correspond in position to said terminal passages, respectively; and
a plurality of terminals, each of said terminals having a connecting end disposed in the corresponding terminal passage, a mating end disposed to electrically contact the circuit board and a securing portion connecting said connecting end and said mating end, said connecting end being capable of electrical contact with the matching electrical connector, said securing portion being received in the corresponding recess so as to be positioned relative to said insulating housing, by means of the arrangement that said connecting face and said mating face of said insulating housing are disposed at right angle relative to each other, the matching electrical connector being capable of coupling with said connecting face in a direction parallel to the direction of extension of the circuit board and electrically contacting the corresponding terminals in said power socket region and said signal socket region.

2. The electrical connector as claimed in claim 1, wherein said insulating housing is further provided with a positioning device for connection with the circuit board.

3. The electrical connector as claimed in claim 2, wherein said positioning device includes two positioning posts which are disposed at two opposite ends of said mating face of said insulating housing and which project in a direction away from said mating face, the circuit board being provided with positioning holes in positions corresponding to said positioning posts so as to receive said positioning posts respectively.

4. The electrical connector as claimed in claim 2, wherein two sides of said insulating housing has a first lateral side and a second lateral side at two sides thereof along a lengthwise extending direction, said positioning device including two outwardly projecting lug portions which are respectively provided on said first lateral side and said second lateral side, two receiving holes extending respectively through and perpendicularly to said lug portions, and two plate locking elements corresponding retained in said receiving holes, said plate locking element each having an elastic engaging portion projecting from said lug portion, the circuit board being provided with fastening holes corresponding in position to said plate locking elements, respectively, to permit passage of said elastic engaging portions therethrough for retaining and securing purposes.

5. The electrical connector as claimed in claim 1, wherein said recesses in said flange of said insulating housing can be further divided into recesses of a first category and recesses of a second category, said recesses of the first category having a determined depth in the direction of said connecting face, said recesses of the second category having a depth in the direction of said connecting face which is larger than that of said recesses of the first category such that connecting ends of said terminals that are correspondingly retained in said recesses of the second category can project a determined distance in the direction of said connecting face compared to said connecting ends of said terminals that are correspondingly retained in said recesses of the first category.

6. The electrical connector as claimed in claim 5, wherein said end face of said insulating housing is provided with a recessed face that corresponds in position to said recesses of the second category and that is recessed in the direction of said connecting face such that length of said terminal passages correspondingly communicated with said recessed face is shorter than that of said terminal passages adjacent thereto.
